(19) United States
(12) Patent Application Publication
(10) Pub. No.: US 2024/0047205 A1
(43) Pub. Date: Feb. 8, 2024

(54) Transfer of Epitaxial Compound Semiconductor Layers From a Van Der Waals Interface Using Direct Wafer Bonding

(71) Applicant: Kyusang Lee, Charlottesville, VA (US)

(72) Inventor: Kyusang Lee, Charlottesville, VA (US)

(21) Appl. No.: 18/345,790

(22) Filed: Jun. 30, 2023

Related U.S. Application Data
(63) Continuation of application No. 17/880,692, filed on Aug. 4, 2022.
Application No. 17/880,692 is a continuation of application No. 18/209,968, filed on Jun. 14, 2023.

(51) Int. Cl. H01L 21/02

(52) U.S. Cl. CPC H01L 21/0254; H01L 21/02568; H01L 21/0262; H01L 21/02595

(57) ABSTRACT

Methods to fabricate compound semiconductor and Ga-face and N-face GaN thin film structures using processes that include remote epitaxy and direct bonding of a semiconductor membrane onto a host substrate. The methods disclosed include transfer by 1) direct wafer bonding, 2) transfer direct bonding by double stressor layer, 3) transfer direct bonding by supporting layer, and 4) transfer direct bonding by SOG layer. Advantageously these direct bonding methods connect two wafer surfaces without requiring any adhesive or additional materials that would otherwise be necessary to promote adhesion between the two adjacent surfaces. These methods support development of bonded platform structures suitable for microelectronics, microtechnologies, sensors, MEMs, optical devices, biotechnologies, and 3D integration. Direct bonding can be performed in conventional wafer bonder.

### CROSS-REFERENCE TO RELATED APPLICATIONS

The present continuation application claims priority to the following patent applications, assigned to the assignee of the present invention, the contents of which are incorporated by reference: U.S. patent application Ser. No. 17/880,692, filed Aug. 8, 2022, entitled “Monolithic Remote Epitaxy of Compound Semiconductors and 2D Materials”, and U.S. patent application Ser. No. 18/209,968, filed Jun. 14, 2023, entitled “Direct Preparation of Pseudo-Graphene on a Silicon Carbide Crystal Substrate”.

### BACKGROUND

### (1) Technical Field

The present invention relates to semiconductor fabrication processes, and particularly to processes for creating compound semiconductors including III-nitride semiconductor membranes and attaching the membranes to host substrates.

### (2) Background

Much of the electronics age has relied upon semiconductor integrated circuits (ICs) based on silicon. In over half a century, engineers and manufacturers have made vast strides in silicon manufacturing, IC design, and semiconductor applications. These decades of development have resulted in such economies of scale that silicon-based ICs are very inexpensive and the tools and techniques for manufacturing such ICs are well-known and wide-spread. However, Moore's Law suggests that researchers may be reaching the theoretical limits of silicon-based semiconductors.

Accordingly, research scientists and semiconductor manufacturers have long searched for more robust alternatives to silicon for numerous applications. A strong contending alternative to silicon has emerged: the nitrides of periodic table group III metal elements (commonly known as “III-nitride” semiconductors), which possess a number of properties that are simply not accessible in any other family of semiconductors, including a high dielectric breakdown voltage and a bandgap that spans from the infrared to the deep ultraviolet.

III-nitride semiconductors are a subset of III-V semiconductors, which comprise semiconductor alloys that include an element having three (III) valence electrons and an element having five (V) valence electrons. Group III elements include boron (B), aluminum (Al), gallium (Ga), and indium (In), while group V elements include nitrogen (N), phosphorous (P), arsenic (As), and antimony (Sb). Binary III-nitride semiconductors include gallium nitride (GaN), aluminum nitride (AlN), indium nitride (InN), and boron nitride (BN). III-nitride semiconductor alloys may also be ternary (comprising three elements, such as AlGaN) or quaternary (comprising four elements, such as AlGaInN). Other III-nitride semiconductors include, but are not limited to, hexagonal BN, AlₓGa₁₋ₓN, InₓGa₁₋ₓN, BₓGa₁₋ₓN, AlₓIn_{y}Ga_{1-x-y}N, InₓAl₁₋ₓN, GaₓAl₁₋ₓN, BₓAl₁₋ₓN, InₓGa_{y}Al_{1-x-y}N, AlₓIn₁₋ₓN, GaₓIn₁₋ₓN, AlₓGa_{y}In_{1-x-y}N, h-GaₓB₁₋ₓN, and their alloys. III-nitride semiconductors crystallize in their most stable form into a wurtzite crystallographic structure with nitrogen atoms forming a hexagonal close-packed (hcp) structure and the group III atoms occupying half of the tetrahedral sites available in the hcp lattice.

A III-nitride semiconductor of particular interest is GaN. One of the most significant advantages of gallium nitride over silicon is its bandgap, which gives it various electrical properties that equip it for higher power applications. GaN has a bandgap of about 3.2 electron volts (eV) compared to about 1.1 eV for Si, and accordingly GaN-based field-effect transistors (FETs) exhibit larger breakdown voltages and more thermal stability at higher temperatures. GaN's breakdown field is about 3.3 MV/cm compared to about 0.3 MV/cm for Si, which makes GaN 10 times more capable of supporting high voltages before failing. Silicon has an electron mobility of about 1500 cm²/Vs compared to up to about 2000 cm²/Vs for GaN. Thus, electrons in GaN crystals can move over 30% faster than in Si. This higher electron mobility for GaN enables higher switching frequencies than for Si, a distinct advantage for use in high-frequency RF components. A further advantage of GaN devices is that they may be much smaller in size than Si devices having comparable performance.

A typical GaN FET includes a thin layer of aluminum gallium nitride (AlGaN) formed on top of a thin GaN crystal. A strain is created at the AlGaN/GaN interface that induces a compensating two-dimensional electron gas (2DEG). This 2DEG is used to efficiently conduct electrons when an electric field is applied across it. The 2DEG is highly conductive, in part due to the confinement of the electrons to a very small region at the AlGaN/GaN interface, which increases the mobility of electrons from about 1000 cm²/Vs in unstrained GaN to between 1500 and 2000 cm²/Vs in the 2DEG region. This characteristic allows fabrication of GaN-based High Electron Mobility Transistors (HEMTs) transistors and integrated circuits that feature higher breakdown strength, faster switching speed, and lower on-resistance than comparable silicon solutions.

GaN crystals may be epitaxially grown on sapphire, silicon carbide (SiC), and Si substrates, despite the mismatch of lattice constants. When epitaxially grown on a substrate, III-nitride semiconductors can have two different orientations: metal-face (e.g., Ga-face) and nitride-face (N-face). The orientation of the final epilayer is a function of the original substrate orientation, buffer growth, and doping conditions.

Epitaxy is a process by which a deposited film is forced into a high degree of crystallographic alignment with the atomic lattice of a substrate. Several epitaxy techniques are available, including molecular beam epitaxy (MBE), epitaxial metal-organic chemical vapor deposition (MOCVD), hydride vapor phase epitaxy (HVPE) and atomic layer epitaxy (ALE). In all cases, the deposition process must be controlled enough to allow the atoms to rearrange themselves on the surface according to the lattice orientation of the substrate. Contamination of the substrate surface by impurities must be kept minimal to avoid disturbing the epitaxial alignment.

For a variety of reasons, including 1) defect problems caused by lattice constant mismatches, 2) the desire to easily remove or “exfoliate” a GaN crystal from an initial substrate to create a GaN membrane, 3) provide the capability to reuse the parent substrate multiple times, and 4) reduce production costs, a technique known as “remote epitaxy” has been developed. The remote epitaxy technique grows III-nitride epilayers “remotely” on two-dimensional (2D) materials, forming an interlayer between a selected substrate (e.g., SiC) and the III-nitride epilayers as a part of the process. Remote epitaxy can effectively grow crystalline compound semiconductor epilayers using a two-dimensional (2D) material interlayer without generating entailed dislocations as long as the potential field from the underlying substrate is strong enough to penetrate through the 2D material interlayer and affect the arrangement of deposited III-nitride material. The 2D material interlayer may be an amorphous, polycrystalline, or single crystal material, such as graphene. Further details regarding remote epitaxy may be found in U.S. patent application Ser. No. 17/880,692 referenced above.

### Compound Semiconductor Epilayers and Membranes

The 2D material interlayer has a weak van der Waals interaction with the overlaying GaN-based epilayers. Unlike ionic or covalent bonds, van der Waals attraction does not result from a chemical electronic bond, and is comparatively weak and therefore more susceptible to disturbance. Accordingly, a thin-film GaN crystal or membrane comprising the GaN epilayers may be separated from the 2D material interlayer by applying a minimal or small mechanical force, generally using a layer transfer technique to attach the GaN crystal to a secondary substrate (e.g., a handle wafer or the like).

The resulting free-standing GaN-based membrane can provide extra degrees of freedom in its functional implementation, while the planar form factor is compatible with modem electronic processing allowing production scalability. Additionally, the adoption of free-standing GaN-based membranes instead of bulk materials provides significant cost savings for the production of electronics, where the major cost of manufacturing is usually material related.

The high-quality surface structures on free-standing semiconductor membranes can be attained by utilizing a combination of remote epitaxy and 2D material-based layer transfer (2DLT) processes. The remote epitaxy technology provides the capability for growing semiconductor epilayers ‘remotely’ from the substrate within a certain interspacing gap, without mechanical failures such as defect and crack behavior as long as the potential field from the substrate is strong enough to penetrate through 2D material interlayers. Once the semiconductor epilayer is grown, the interface between the epilayer and the 2D materials interface can be separated with minimal involvement of dislocations owing to the weak vertical interaction of the 2D materials with the epilayer.

Direct wafer bonding is a method of forming a heterointerface or heterojunction (a heterojunction is an interface that occurs between two layers or regions of dissimilar crystalline semiconductors) between two material layers, with benefits such as the possibility to combine semiconductor epilayers with various different substrate materials. Direct wafer bonding can be a useful technique to combine materials that have a high lattice mismatch or chemical instabilities. Direct bonding enables the formation of atomic bonds across atomically flat surfaces of different materials without introducing threading dislocations or stacking faults at the interface. It would be an advantage to improve the direct wafer bonding process and its application to III-nitride (particularly GaN) semiconductors, to peel off and to transfer GaN-layered structures. The present invention addresses this challenge.

### SUMMARY

Methods are disclosed to fabricate Ga-face and N-face GaN thin film structures using direct bonding of a GaN membrane onto a host substrate, and more generally using compound semiconductor thin film structures. The methods disclosed include transfer by 1) direct wafer bonding, 2) transfer direct bonding using two stressor layers, 3) transfer direct bonding by supporting layer, and 4) transfer direct bonding by SOG layer.

Advantages include:
These four transfer direct bonding methods directly connect two wafer surfaces without requiring any adhesive or additional materials that would otherwise be necessary to promote adhesion between the two adjacent surfaces.
The direct bonding methods allow different materials to be stacked together without causing problems that might otherwise result from the crystalline relationship between the different materials.
It is also well suited to 2D layer transfer (2DLT) techniques.
The stacked structures formed by transfer direct bonding are much more resistant to high temperatures, and therefore can be used in subsequent high temperature processes that would not be possible if polymer adhesive bonding or low melting point metal soldering was used instead of direct bonding.
Furthermore, these methods can result in the emergence and support future development of bonded platform structures suitable for novel applications such as microelectronics, microtechnologies, sensors, MEMs, optical devices, biotechnologies, and 3D integration.

A disclosed method of fabricating a Ga-face thin film structure includes epitaxially forming III-nitride GaN epilayers over a 2D material interlayer on a growth substrate and lifting off the epilayers from the 2D material interlayer. A host substrate is directly bonded to the bottom surface of the GaN epilayers. Direct bonding can be performed in conventional wafer bonder. The top surface of the GaN epilayers is exposed to provide a Ga-face thin film structure.

In one embodiment, prior to lifting off the epilayers, a top host substrate is directly bonded to the top surface of the GaN epilayer. In this embodiment, exposing the top surface of the GaN epilayers includes removing the top host substrate.

In another embodiment, a method of fabricating a GaN membrane thin film structure using two stressor layers includes depositing a first stressor layer over the GaN epilayers and applying a first thermal release tape over the first stressor layer. The thermal release tape is used to lift off the GaN epilayers from the 2D material interlayer on the growth substrate, which exposes the bottom surface of the GaN epilayers. A second stressor layer is deposited on the bottom surface of the GaN epilayers, and a second thermal release tape is applied over the second stressor layer. The first thermal release tape and the first stressor layer are removed. A host substrate is provided, and the top surface of the GaN epilayers is bonded to the host substrate using any appropriate bonding method such as direct bonding. The second stressor layer is removed from the epilayers to expose the top surface of the GaN epilayers and thereby provide an N-face thin film structure including the GaN epilayers and the host substrate.

In another embodiment, prior to lifting off the epilayers, a Ti/Ni stressor layer is formed on the top surface of the GaN epilayer, a spin on glass (SOG) layer is formed on the Ti/Ni stressor layer, and a substrate is attached to the SOG layer while curing the SOG layer, so that the substrate is attached when cured. In this embodiment, exposing the top surface of the GaN epilayers includes removing the SOG layer, the substrate, and the Ti/Ni stressor layer.

Lifting off the GaN epilayers from the 2D material interlayers may include applying mechanical shear force. Particularly, lifting off may include mechanically guiding the fracture front across the weak van der Waals interactions dominating the surface of 2D material interlayers.

In another embodiment, a fabrication method includes epitaxially forming GaN epilayers over a 2D material interlayer on a growth substrate, depositing a Ti adhesion layer over the epilayers, depositing an Ni stressor layer over the Ti adhesion layer, applying thermal release tape to the Ni stressor layer, and using the thermal release tape, lifting off the GaN epilayers from the 2D materials layer and the growth substrate to expose the bottom surface of the GaN epilayers. In this embodiment, a PMMA layer is applied to the bottom surface and an intermediate substrate is attached to the PMMA layer. A handling layer is formed, and the PMMA layer is removed. This structure is directly bonded onto a host substrate. The handling layer and the Ti adhesion layer, to provide a Ga-face final thin film structure.

A method of fabricating an N-face GaN membrane thin film structure using direct wafer bonding is disclosed that includes epitaxially forming GaN epilayers over a buffer layer and a 2D material interlayer on a growth substrate, providing an exposed top surface of the GaN epilayers, directly wafer bonding a host substrate to the top surface of the GaN epilayers, lifting off the GaN epilayers and the host substrate from the 2D material interlayer to expose the buffer layer attached to the bottom surface of the GaN epilayers, and removing the buffer layer from the GaN epilayers to expose the bottom surface of the GaN epilayers and thereby provide a N-face thin film structure including the GaN epilayers and the host substrate.

A method of fabricating a GaN membrane is disclosed that includes epitaxially forming GaN epilayers over a 2D material interlayer on a growth substrate, directly wafer bonding a host substrate to the top surface of the GaN epilayer, lifting off the GaN epilayers and the host substrate from the 2D material interlayer, and removing the host substrate from the GaN epilayers to provide a GaN membrane.

The details of one or more embodiments of the invention are set forth in the accompanying drawings and the description below. Other features, objects, and advantages of the invention should be apparent from the description and drawings, and from the claims.

### BRIEF DESCRIPTION OF THE DRAWINGS

FIG. 1 is a cross-sectional view of a film structure that includes GaN epilayers on directly grown 2D material interlayers on a III-nitrides substrate.

FIG. 2A is a flow chart that shows steps for direct wafer bonding to create a semiconductor membrane structure.

FIG. 2B is a flow chart showing several methods for transferring epilayers from a first host substrate to a second host substrate using direct wafer bonding.

FIG. 3 is a cross-sectional view of a first host substrate and a film structure including the initial epilayer structure situated in a wafer bonder to directly bond the epilayers to the host substrate.

FIG. 4 is a cross-sectional view of a bonded structure resulting from bonding the first host substrate to the epilayers as shown in FIG. 3.

FIG. 5 is a cross-sectional view of a film structure with GaN epilayers and the first host substrates being lifted off (e.g., by mechanical shear force or pulling) from the 2D material interlayers.

FIG. 6 is a cross-sectional view showing the resulting bonded structure from the separation of FIG. 5, including the first host substrate and the GaN epilayers with an exposed N-face.

FIG. 7 is a cross-sectional view showing the bonded film structure of FIG. 6 prior to attachment to a second host substrate.

FIG. 8 is a cross-sectional view of a double-substrate structure resulting after attachment of the second substrate in FIG. 7, showing the GaN epilayers 120 bonded between the first and second host substrates.

FIG. 9 is a cross-sectional view of the first host substrate being removed from the top surface of the GaN epilayers, to provide the final structure.

FIG. 10 is a cross-sectional diagram that illustrates grinding the first host substrate to expose the Ga-face of the GaN epilayers, and polishing it provide a polished GaN surface.

FIG. 11 is a cross-sectional view of the bonded structure shown in FIG. 6, illustrating the first host substrate being removed directly from the GaN epilayers.

FIG. 12 is a cross section of the structure after the removal of the first host substrate as shown in FIG. 11, providing a freestanding membrane.

FIG. 13 is a cross-section showing that the freestanding membrane can be attached to other structures such as a substrate.

FIG. 14 is a cross-sectional view of the Ga-face final structure after the first substrate has been removed.

FIG. 15 is a cross-sectional view of a multilayered structure that shows a buffer layer between the 2D interlayers and the GaN epilayers.

FIG. 16 is a cross-sectional view showing a film structure including a first host substrate and GaN epilayers, with the buffer layer still attached to the bottom surface of the epilayers.

FIG. 17 is a cross-sectional view of the N-face GaN film structure of FIG. 16 after removal of the buffer layer.

FIG. 18 is a flow chart that shows steps of a transfer method that uses two stressor layers for directly bonding a membrane to a host substrate using remote epitaxy.

FIG. 19 is a cross-sectional view of a film structure in which thermal release tape has been applied over a first stressor layer formed on top of GaN epilayers formed on directly grown 2D material interlayers on III-Nitrides substrates.

FIG. 20 is a cross-sectional view of the film structure including GaN epilayers being lifted off at the 2D material interface.

FIG. 21 is a cross-sectional view showing the structure resulting after a second stressor layer is formed over the bottom surface, and a second thermal release tape is applied over the second stressor layer.

FIG. 22 is a cross-sectional view that shows the epilayer and second stressor layer structure and the host substrate prior to the attachment to the Ga-face of the epilayers.

FIG. 23 is a cross-sectional view that illustrates bonding the GaN epilayers to a host substrate using a conventional wafer bonder.

FIG. 24 is a cross-sectional view of the film structure after bonding the GaN epilayer to the host substrate, and after second stressor layer has been removed, providing an N-faced film structure.

FIG. 25 is a flow chart of steps of the transfer method that uses a supporting layer for directly bonding a membrane to a host substrate using remote epitaxy.

FIG. 26 is a cross-sectional view of a film structure in which thermal release tape has been applied over a Ti/Ni stressor layer formed on top of GaN epilayers formed on directly grown 2D material interlayers on III-Nitrides substrates.

FIG. 27 is a cross-sectional view of lifting off the film structure including the GaN epilayer from its interface with the 2D material interlayers.

FIG. 28 is a cross-sectional view that shows the intermediate substrate prior to attachment to the N-face of the epilayers.

FIG. 29 is a cross-sectional view that shows a PMMA supporting layer formed between the GaN epilayers and the coated glass (or Si) substrate to attach the epilayer film structure to the substrate, after the thermal tape has been removed.

FIG. 30 is a cross-sectional view of the film structure of FIG. 29 after a handling layer has been coated on top of Ti adhesion layer.

FIG. 31 is a cross-sectional view of the film structure of FIG. 30 illustrating removal of the PMMA supporting layer from the gap between the epilayer and the substrate.

FIG. 32 is a cross-sectional view of the film structure of FIG. 31 after removal of the PMMA supporting, illustrating that the GaN epilayers may be wet transfer direct bonded onto a host substrate in DI water.

FIG. 33 is a cross-sectional view that shows the final structure after the handling layer and Ti adhesion layer are removed, the final structure including the GaN epilayer bonded to the host substrate, which provides a Ga-faced film structure.

FIG. 34 is a flow chart that shows steps of a transfer method that uses a SOG (Spin on glass) layer for directly bonding a membrane to a host substrate, to create a semiconductor membrane structure.

FIG. 35 is a cross-section view that shows a film structure including a spin on glass (SOG) layer and a Ti/Ni stressor layer formed on the top surface of the epilayer of an initial epilayer structure.

FIG. 36 is a cross-sectional view of the film structure including the SOG layer, stressor layers, and GaN epilayers being lifted off from the substrate at the 2D material interface.

FIG. 37 is a cross-sectional view that illustrates directly bonding the GaN epilayers to the host substrate(s) using a conventional wafer bonder.

FIG. 38 is a cross sectional view of the structure resulting from bonding shown in FIG. 37 in which the epilayer is directly bonded to the host substrate.

FIG. 39 is a cross-sectional view that shows the film structure after removing the substrate, SOG layer and Ni/Ti stressor layer, including the GaN epilayer bonded to the host substrate, which provides a Ga-faced structure.

Like reference numbers and designations in the various drawings indicate like elements.

### DETAILED DESCRIPTION

Methods are described to use remote epitaxy and direct bonding to fabricate a thin film structure that includes a GaN membrane on a host substrate. Direct bonding for purposes herein includes wafer bonding methods that directly connect the two surfaces, and do not require any adhesive or additional materials.

For purposes of description, a multilayer structure may be referenced as a single element or layer; it should be understood that the reference to a single layer or element may include multiple layers. For example, a substrate may include multiple layers, and it should be understood that a reference to a substrate includes those multiple layers.

The examples below generally mention use of III-N, III-V, II-VI, Si, sapphire, SiC, or complex oxides as thin film structures, substrate materials, and/or epilayers, but it should be understood that the inventive methods and structures are not limited to those compound semiconductors, but extend to other compound semiconductors made from two or more elements, including (but not limited to) binary alloys (e.g., IV-IV, I-VII, IV-VI, V-VI, II-V, and IV-VI compound semiconductors), ternary alloys (e.g., InGaAs), quaternary alloys (e.g., AlInGaP, InAsSbP), and even more complex compound semiconductors.

### (1) Initial Epilayer Structure

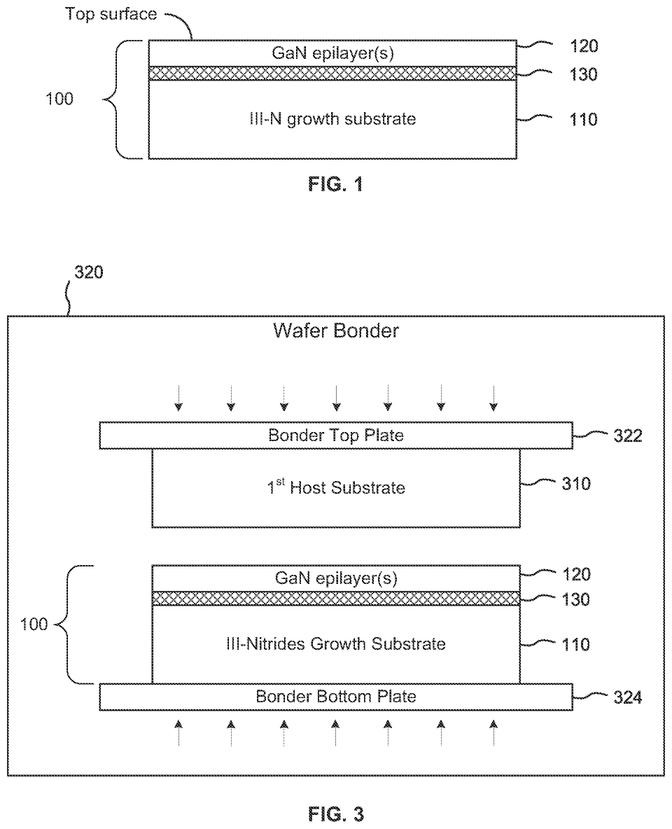

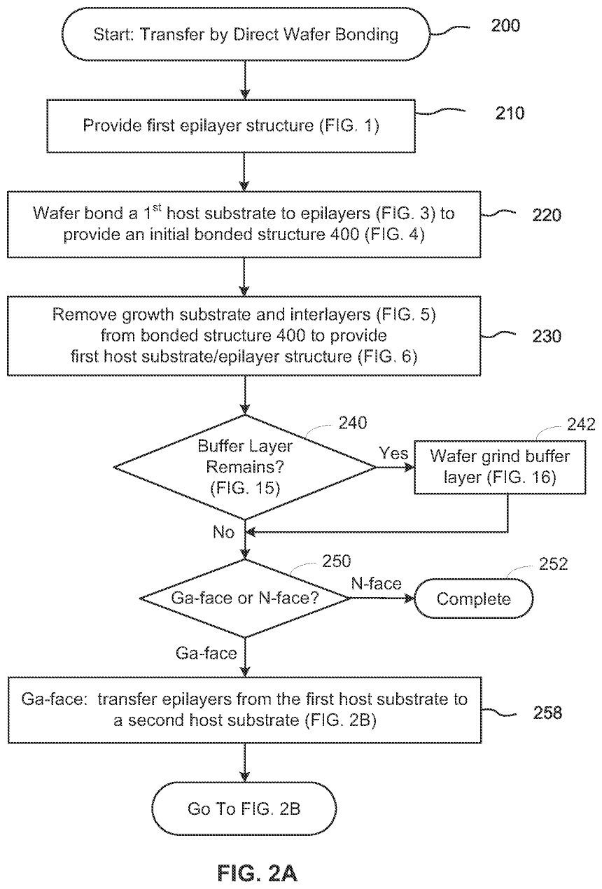

The methods described herein begin with a multilayer semiconductor structure, which is described next. FIG. 1 is a cross-sectional view that shows the initial epilayer structure 100, including a III-N growth substrate 110, one or more GaN epilayers 120 grown over the substrate 110, and a 2D material interlayer 130 (which may also be referred to as a 2D interlayer) formed between the substrate 110 and the epilayers 120. The initial epilayer structure 100 is provided by epitaxially forming the GaN epilayers 120 over the 2D material interlayer 130, on the growth substrate 110.

Generally, the III-N growth substrate 110 is suitable for growing epitaxial GaN or other III-nitride layers. The III-N growth substrate 110 may comprise bulk materials such as III-N, III-V, II-VI, Si, sapphire, SiC, or complex oxides or may comprise a buffer-layered common substrate such as III-N, III-V, II-VI, SiN, SiC, complex oxides or other oxide templates formed on a host substrate such as Si, sapphire. For example, a substrate made of silicon carbide (SiC) is known to provide a strong seed for growth of gallium nitride (GaN), which is a III-nitride material. Other useful III-nitride materials include aluminum nitride (AlN), indium nitride (InN), and boron nitride (BN).

The 2D material interlayers 130 (such as graphene, amorphous graphene, pseudo-graphene, amorphous BN (a-BN), polycrystalline BN, cubic BN (c-BN), and hexagonal BN (h-BN)) can be formed by direct growth on the substrate 110. The 2D material interlayers may have thicknesses ranging from 1 nm to 100 nm and can be grown in an MBE or MOCVD chamber, for example.

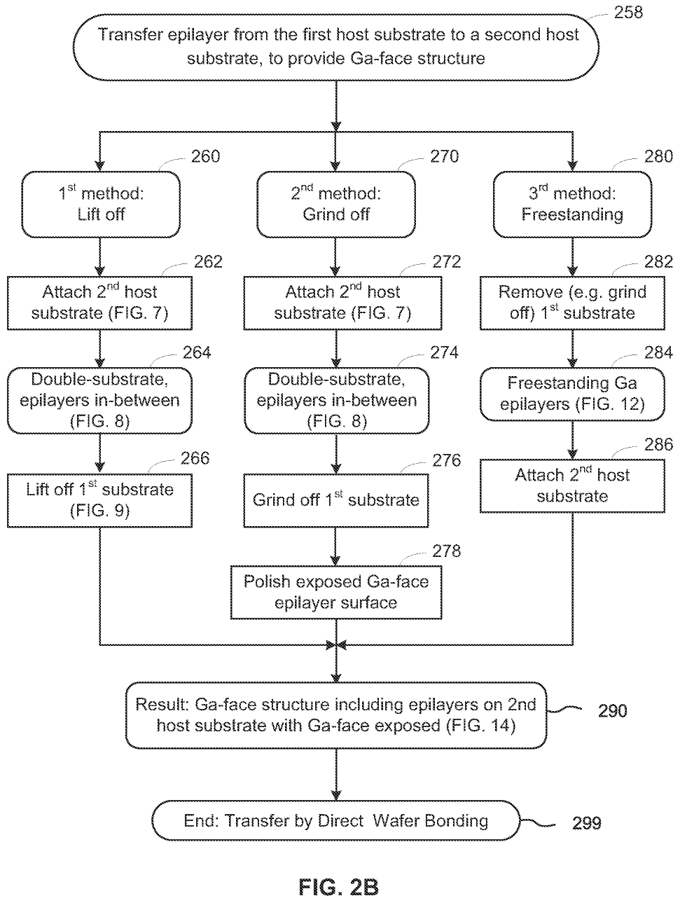

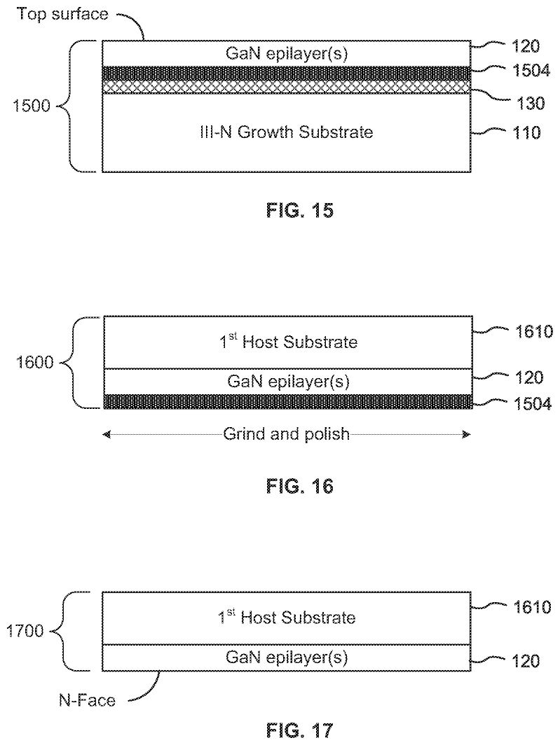

In one example, using an MBE growth process, an a-BN layer is grown by evaporating a boron ingot by an electron-beam gun, and flowing N2 gas from an RF plasma source into the chamber. In some embodiments, an additional buffer layer (1504, see FIG. 15) may be provided between the interlayer 130 and the GaN epilayer 120. In that embodiment, additional steps may be required in the process, such as shown in STEP 240 (FIG. 2) and discuss with reference to FIGS. 15-17.

Interlayer growth temperatures can range from 700° C. to 900° C. or more, as measured by a pyrometer. In one example a graphene interlayer can be grown using both gaseous and solid sources for carbon at substrate temperatures within the range between 1000° C. to 1200° C.

An example of a graphene buffer layer is described in a related application by the same owner: U.S. patent application Ser. No. 18/209,968, filed Jun. 14, 2023, entitled “Direct Preparation of Pseudo-Graphene on a Silicon Carbide Crystal Substrate”, which has been incorporated by reference. The method disclosed therein includes providing an SiC substrate, epitaxially forming a graphene structure on the substrate that includes a graphene layer and a pseudo-graphene (PG) buffer layer situated between the graphene layer and the substrate. A plasma dry etching process is used to remove the graphene layer and expose the pseudo-graphene layer. A GaN membrane is then formed on the PG layer.

After the 2D interlayers 130 are grown, the epilayers 120 are grown on the 2D interlayers 130. The thickness of the epilayers 120 may range from 0.1 um to 10 um. In one embodiment the GaN epilayers, with a Ga-face on top and an N-face on the bottom, can be grown via MBE, MOCVD, and HVPE tool on the formed 2D interlayers 130, such as by direct growth on the III-Nitrides growth substrate 110 (FIG. 1). The GaN epilayers 120 can be grown to a thickness ranging from 0.1 um to 10 um at growth temperatures (600° C. to 900° C.) under atmospheric pressure in an N2 RF plasma.

The initial epilayer structure 100 (FIG. 1) is now complete. The following methods begin with this initial epilayer structure 100.

### (2) Transfer by Direct Wafer Bonding

FIGS. 2A and 2B are flow charts that show steps for direct wafer bonding to create a semiconductor membrane structure: FIG. 2A shows processes including direct wafer bonding, and FIG. 2B shows several methods for transferring epilayers from a first host substrate to a second host substrate, to create a Ga-face semiconductor structure. FIGS. 3-17 are cross-sectional views of multilayer structures at intermediate and result stages of the transfer process, described in the flow charts of FIGS. 2A and 2B.

The wafer bonding process (STEP 200) starts by providing (STEP 210) the first epilayer structure (ES) 100 described with reference to FIG. 1, comprising the III-N growth substrate 110, the plurality of GaN epilayers 120, and the 2D material interlayer 130 situated between the substrate and the epilayers.

Next (STEP 220, FIG. 3) a host substrate is wafer-bonded to the top surface of the GaN epilayers 120. The host substrate comprises a suitable substrate such as III-N, III-V, II-VI, SiC, Si, SiO₂, sapphire, GaN templates on silicon or sapphire, AlN template on Si or sapphire, GaAs template on sapphire, SiN template on sapphire, or other oxide templates, complex oxides, flexible molybdenum (Mo), titanium (Ti), tantalum (Ta), copper (Cu), and hafnium (Hf) metal foils, or a combination of these materials.

FIG. 3 is a cross-sectional view of a first host substrate(s) 310 and the initial epilayer structure 100 situated between a bonder top plate 322 and a bonder bottom plate 324 in a conventional wafer bonder 320. The wafer bonder 320 supplies compressive force to the plates 322,324. In one embodiment the top surface of the GaN epilayers 120 and the first host substrate(s) 310 are directly bonded under a chamber vacuum of 10⁻³ Torr by the wafer bonder 320 using the compressive force shown in FIG. 3. The bonding temperature can range from 100° C. to 500° C., the bonding pressure can range from 1 MPa to 50 MPa, and the bonding time can range from 1 minute to 60 minutes.

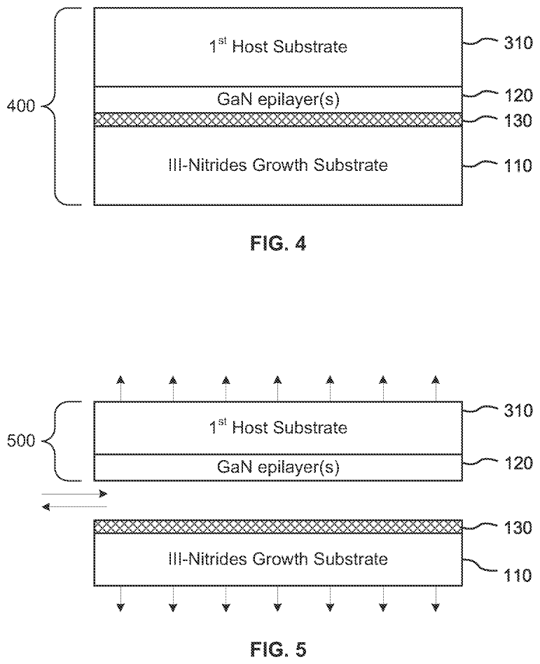

FIG. 4 is a cross-sectional view of the initial bonded structure 400 resulting from bonding (STEP 220) the first host substrate 310 to the GaN epilayers 120 as shown in FIG. 3.

Next (STEP 230 and FIG. 5) the GaN epilayer 120 and the first substrate are separated from the 2D interlayer 130. FIG. 5 is a cross-sectional view illustrating the separation process; showing the bonded structure 500 including the first host substrate 310 and the GaN epilayers 120 being separated from the 2D interlayer 130 and the growth substrate 110. In some embodiments, mechanical shear force (side-to-side) and/or pulling force (vertical) at the 2D material interface may be applied to lift off (peel) the first substrate/epilayer structure 500 from the 2D interlayer 130 and the growth substrate 110.

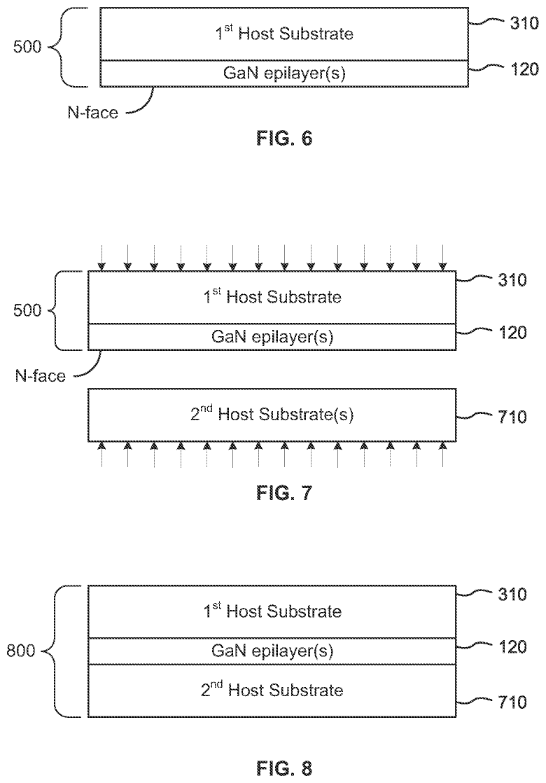

FIG. 6 is a cross-sectional view showing the resulting first substrate/epilayer structure 500 including the first host substrate 310 and the GaN epilayers 120. It may be noted that the GaN epilayers 120 have an exposed N-face in the first substrate/epilayer structure 500.

Returning to the flow chart of FIG. 2A, a determination is made (STEP 240) as to whether or not there is an additional buffer layer on the exposed N-face. In some embodiments a buffer layer exists between the epilayers 120 and the interlayers 130, or there may be some residue of the 2D interlayers left after separation. In such embodiments, the GaN buffer layer (or residue) may need to be removed, e.g., by mechanical removal or a wafer grinding process, followed by polishing the GaN layer. The next step (STEP 242) shown is performed if this additional buffer layer exists. This (STEP 242) is described and shown with reference to FIGS. 15-17.

FIG. 15 is a cross-sectional view of a multilayered structure 1500 that shows a buffer layer 1504 between the 2D interlayers 130 and the GaN epilayers 130. In this instance, in the 2DLT process when the epilayers 120 are lifted off such as described with reference to FIGS. 5 and 6, the buffer layer 1504 (or residue) may remain attached to the bottom surface of the epilayer 120, rather than fully peeling away from it.

FIG. 16 is a cross-sectional view that shows a bonded structure 1600 including a first host substrate 1610 and GaN epilayers 130, with the buffer layer 1504 still attached to the bottom surface of the epilayers 130 after removal of the interlayers. In this instance, the buffer layer 1504 must be removed to make an N-face structure, or other structures, before further steps such as attaching other device layers. Therefore, the buffer layer 1504 (or residue) can be ground away from the epilayer film remaining on the first substrate/epilayer structure 500, exposing the surface of the N-face of the GaN epilayer. The exposed surface may also be polished, if desired, particularly if an N-face structure is the intended result.

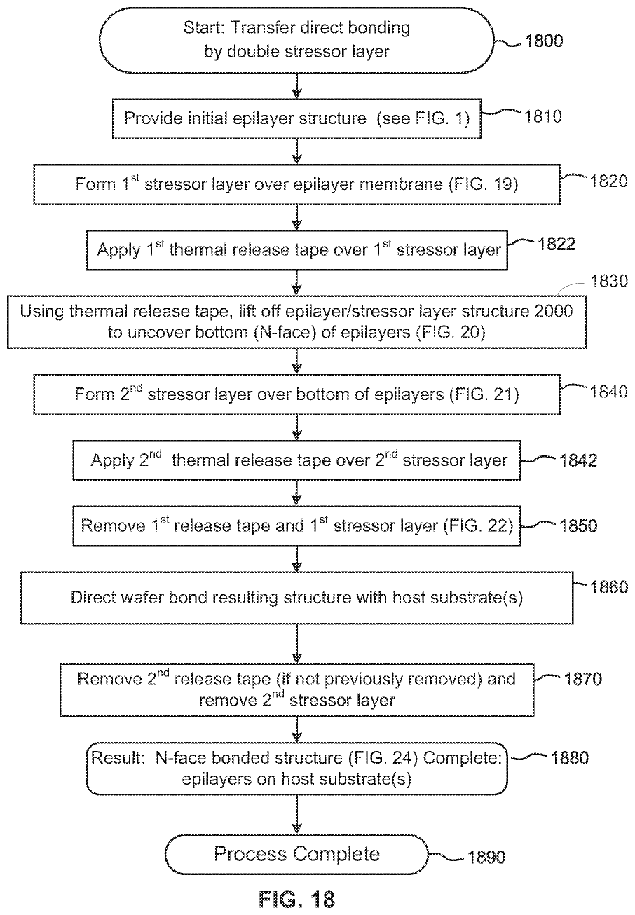

FIG. 17 is a cross-sectional view of the resulting N-face GaN structure 1700 including the first host substrate 1610 and the GaN epilayers 120. This structure 1700 can now be used by itself or as a structure to create other semiconductor structures.

Returning to the flow chart of FIG. 2A, a determination (STEP 250) is made as to whether a Ga-face or an N-face device is desired. The bonded structure 500 shown in FIG. 6, and the bonded structure 1700 shown in FIG. 17, already have an N-face, and it is possible for some embodiments that the N-face is the desired result and in that case, operations are complete (STEP 252).

However, typically a Ga-face device is required, and in that case, steps are performed (STEP 258) to transfer a first the epilayers 120 from the first substrate 310 to a second host substrate. In other words, the epilayer membrane 120 will be transferred from the first host substrate 310 to a second host substrate, in order to provide a Ga-face epilayer structure.

### (3) FIG. 2B: Transferring Epilayers to Second Host

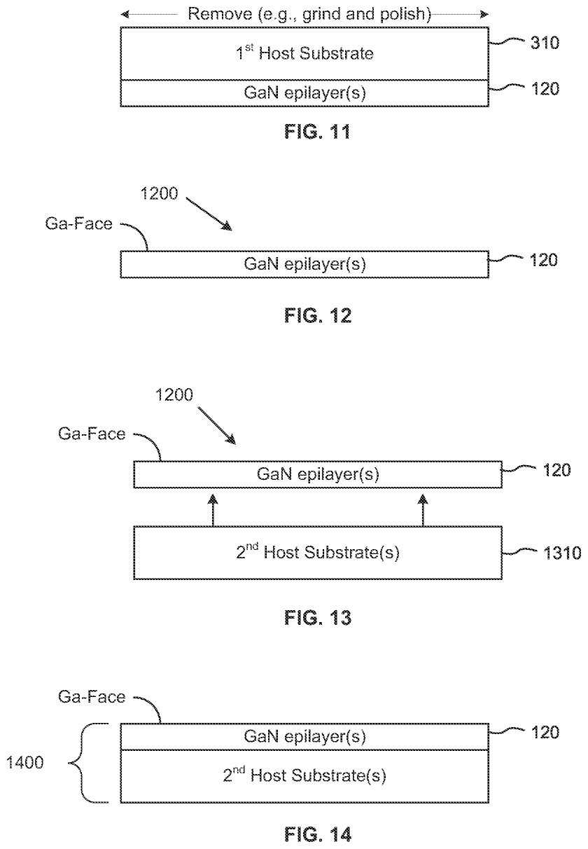

FIG. 2B is a flow chart showing several methods of transferring the epilayers 120 from the first host substrate 310 to a second host substrate, to provide a Ga-face epilayer (STEP 258). A first substrate transfer method 260 is described with reference to FIGS. 7-9, a second transfer method 270 is described with reference to FIGS. 7-8, and 10, and a third transfer method 280 is described with reference to FIGS. 11-13. The resultant structure is shown in STEP 290 and FIG. 14.

The first substrate transfer method 260, which may be termed a “lift-off” method, includes (STEP 262) attaching the N-face of the bonded structure 500 to a second host substrate.

FIG. 7 is a cross-sectional view that shows the bonded structure 500 and a second host substrate 710 prior to attachment. A direct bonding process is used to attach the second host substrate 710 to the lifted-off epilayers 120. In some embodiments, depending upon the specific materials and the desired result, the substrate 710 and epilayers 120 might be just pressed together; in other embodiments a wafer bonder may be useful or necessary.

The resultant structure (STEP 264) is shown in FIG. 8, which is a cross-sectional view of a double-substrate structure 800 resulting after the attachment shown in FIG. 7, showing the GaN epilayers 120 situated in-between between the first and second host substrates.

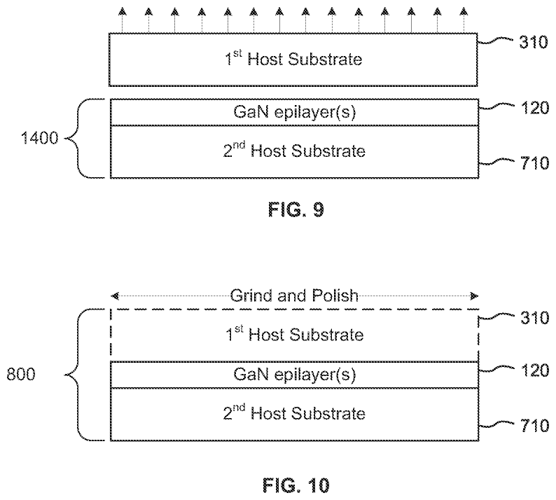

Next (STEP 266) the first host substrate is removed (e.g., lifted off) from the GaN epilayers 120 to expose the top (Ga-face) surface. FIG. 9 is a cross-sectional view of the first host substrate 310 being removed from the top surface of the GaN epilayers 120 to provide the final structure 1400 (shown in FIG. 14). The first host substrate 310 may be lifted off by any method suitable for the materials and interface, such as shear force or others described herein.

In the second method of substrate transfer (STEP 270), the second host substrate 710 is attached (STEP 272) to the bonded structure 500, e.g., as described with reference to STEP 262 and FIG. 7, to provide the double-substrate structure (STEP 274 and shown in FIG. 8) in which the GaN epilayers 120 are situated in-between between the first and second host substrates. To remove the first host substrate 310 using this second method, the first host substrate 310 is ground (STEP 276) and polished (STEP 278) until the Ga-face of the epilayers 120 is exposed and polished. Grinding the substrate and polishing the GaN epilayer surface may be performed by a convention grinder and polisher. FIG. 10 is a cross-sectional diagram that illustrates grinding the first host substrate 310 and polishing the GaN epilayers. The resultant Ga-face GaN structure 1400 is shown in FIG. 14.

FIGS. 11-13 illustrate a third method (STEP 280) that can be used depending upon the materials in the substrate 310 and epilayers 120, and strength of the bonding between them. The first substrate is removed (STEP 282), leaving the freestanding Ga epilayers (STEP 284). For example, in some embodiment the bonding between the substrate 310 and the epilayer 120 may be weak enough that they can be separated by pulling or mechanical shear force and then polished. If the bonding is strong, or the epilayers are thin, removal can be performed by grinding the substrate and polishing the GaN layer, and another substrate or other mechanical device may be used to hold the epitaxial layer 120 in place during the grinding and polishing process. FIG. 11 is a cross-sectional view of the bonded structure 500 illustrating the first host substrate 310 being removed from the epilayers 120.

FIG. 12 is a cross section of the resulting structure from the removal of the first host substrate 310, in which the only the epilayer 120 remains, which provides a freestanding membrane 1210 that can be used as needed to fabricate many embodiments of multilayer structures. This method may be useful in embodiments in which the epilayers 120 alone can be handled without damage, such as if the epilayers 120 have sufficient thickness to provide strength for handling alone.

The freestanding membrane 1210 can be attached to other structures as may be useful. For example (STEP 286) the freestanding epilayer membrane 1210 can be attached to a second host substrate. FIG. 13 is a cross-section showing that the freestanding membrane 1210 can be attached to other structures, such as substrates(s) 1310 to provide a Ga-face structure 1400.

The result (STEP 290) of the first, second, or third methods of substrate transfer is a Ga-face structure including Ga-face epilayers on a host substrate. The steps in the flow chart of FIGS. 2A and 2B are now complete (STEP 299).

FIG. 14 is a cross-sectional view showing the Ga-face final structure 1400 after the first substrate 310 has been removed. The structure 1400 includes the GaN epilayers 120 attached to the second host substrate, with the Ga-face exposed. This final structure 1400 can now be used by itself or as a structure to create other semiconductor structures.

### (4) Transfer Direct Bonding Using Two Stressor Layers

The transfer direct bonding process using two stressor layers includes 1) depositing a first stressor layer up to a critical thickness over III-N (e.g., GaN), III-V, II-VI, SiC, complex oxides, or other oxides epilayers, 2) applying a thermal release tape to the surface of the first stressor layer, 3) mechanically guiding the fracture front across the weak van der Waals interactions dominating the surface of 2D material interlayers to separate the epilayer from the growth substrate, 4) depositing a second stressor layer on the exposed epilayer surface, 5) applying a thermal release tape to the second stressor layer, 6) removing the first release tape and stressor layer, 7) directly transfer bonding the epilayers and host substrate, and 8) removing the second release tape and stressor layer.

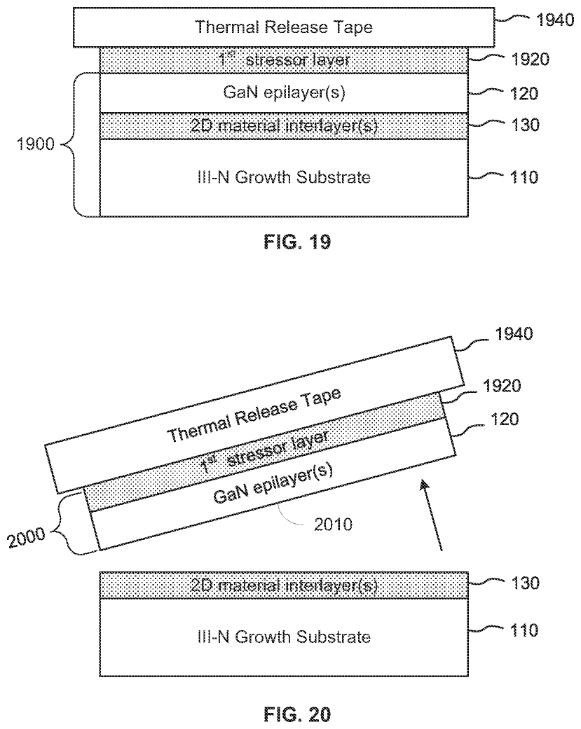

FIG. 18 is a flow chart that shows steps of a transfer method that uses two stressor layers to directly bond a membrane to a host substrate, to create a semiconductor membrane structure. The following FIGS. 19-24 are cross-sectional views of multilayer structures at intermediate and result stages of the transfer process. Alternative embodiments are also disclosed.

The transfer bonding process (STEP 1800) starts by providing an initial epilayer structure (STEP 1810), including a III-N growth substrate 110, a plurality of GaN epilayers 120, and a 2D material interlayer 130 situated between the substrate and the epilayers. The initial epilayer structure is shown at 1900 in FIG. 19, and is described in detail with reference to FIG. 1.

Next (STEP 1820), a first stressor layer 120 is deposited over the GaN epilayers to a critical thickness. Then (STEP 1822) a first thermal release tape is applied over the first stressor layer 120.

FIG. 19 is a cross-sectional view of a film structure in which thermal release tape 1940 has been applied over the Ti/Ni stressor layer 1920, which was formed on top of the initial epilayer structure 1900. The materials in this first stressor layer 1920 may include titanium (Ti) and nickel (Ni), or other suitable materials, and the stressor layer 1920 may include materials such as Ti and Ni. In other embodiments a single layer, two layers, or multiple layers may be implemented to provide the first stressor layer 1920. More generally, in order to exfoliate GaN epilayers at 2D material interlayers by the process as shown in FIG. 20, metal, stressor layers (such as Ni, Ti, Cr, etc.) may be formed in the form of a double layer of Ti/Ni or Cr/Ni on GaN epilayers, with the Ga face on top and the N-face on bottom on formed 2D interlayers by direct growth on III-Nitrides substrate (FIG. 19). In one embodiment, a Ti or Cr layer with thicknesses ranging from 1 nm to 100 nm is grown by electron beam evaporation at about room temperature, and a Ni layer with thickness ranging from 0.1 um to 1 um is grown on top by DC magnetron sputtering.

At STEP 1830, and as shown in FIG. 20, the first stressor layer 1920 and the epilayer 120 (shown at 2000) are then lifted off from the substrate 110 and the 2D interlayers 130, using the thermal release tape 1940. This can be performed by mechanically guiding the fracture front across the weak van der Waals interactions dominating the surface of 2D material interlayers. FIG. 20 is a cross-sectional view showing the thermal release tape 1940 and the resultant film structure 2000 (including the stressor layers and GaN epilayers) being lifted off from the 2D material interlayers 130 and the III-Nitrides substrate 110, at the interface between the epilayers 120 and the 2D interlayers 130. A bottom surface 2010 of the epilayers is now uncovered.

At STEP 1840, a second stressor layer is formed over the uncovered bottom surface of the epilayers, and at STEP 1842, a second thermal release tape is applied over the second stressor layer 2120. FIG. 21 is a cross-sectional view showing the structure resulting from STEPS 1840 and 1842: a second stressor layer 2120 is formed over the bottom surface 2010, and a second thermal release tape 2140 is applied over the second stressor layer 2120.

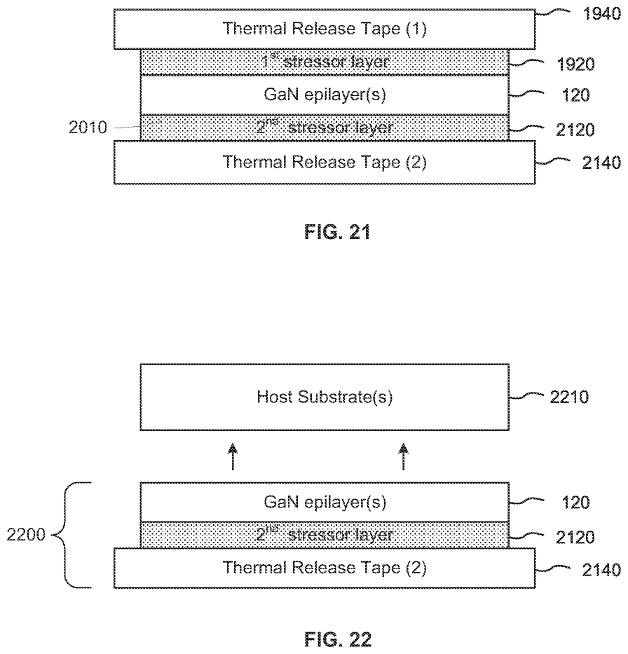

At STEP 1850, the first release tape 1940 and the first stressor layer 1920 are removed, to provide a bonded structure 2200 shown in FIG. 22. In one embodiment, the thermal release tape 1940 is removed through melting the adhesive material between the stressor layers and the release tape at temperatures ranging between 120° C. to 180° C., using a hot plate (not shown). If the first stressor layer 1920 is formed of Ni/Ti or Ni/Cr, the Ni is removed by an appropriate etchant (e.g., a ferric chloride (FeCl₃) etchant), and the Ti or Cr is removed by an appropriate etchant (buffered oxide etchant (BOE) or chromium etchant).

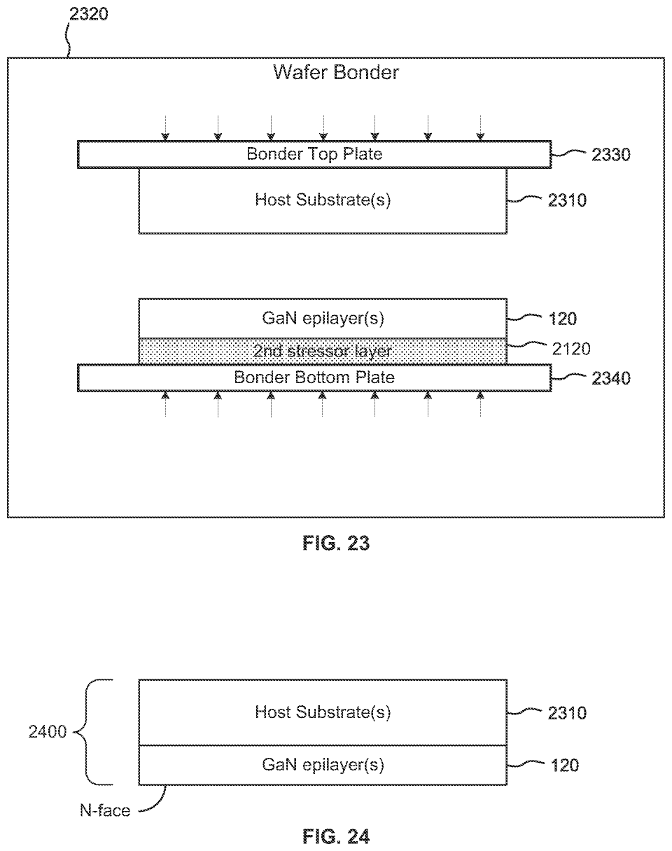

Next (STEP 1860) the epilayer/stressor layer structure 2200 is direct wafer bonded to a suitable host substrate 2210, using a suitable bonding technique. Particularly, the Ga-face of the lifted-off GaN epilayers 120 is bonded to a suitable host substrate 2210 using any appropriate semiconductor bonding process such as direct bonding. In some embodiments, a wafer bonder (shown in FIG. 23) may be needed or useful to bond the GaN epilayers 120 to the host substrate(s) 2210. FIG. 22 is a cross-sectional view that shows the epilayer and second stressor layer structure 2200 and the host substrate 2210 prior to the attachment to the Ga-face of the epilayers 120.

In some bonding methods, it may be useful or practical to keep the second thermal release tape 2140 in place for the bonding process. However, if a wafer bonder is used, as shown in FIG. 23, then the thermal tape will be removed prior to bonding. In one embodiment, the thermal release tape 1940 can be removed through melting the adhesive material between the stressor layer and the release tape at temperatures ranging between 120° C. to 180° C., using a hot plate (not shown).

FIG. 23 is a cross-sectional view that illustrates directly bonding the GaN epilayers 120 to the host substrate(s) 2210 using a conventional wafer bonder 2320 that has a top plate 2330 and bottom plate 2340 that apply compressive bonding pressure. In one embodiment, the GaN epilayers and host substrate(s) are bonded (STEP 1860) at bonding conditions (such as temperature, pressure, and time) under a chamber vacuum of 10⁻³ Torr using the conventional wafer bonder 2320.

At STEP 1870, the thermal tape (if it is still present) is removed, and the second stressor layer 2120 is removed. The result (STEP 1880) is an N-face bonded structure (shown in FIG. 24). The process of direct bonding by double stressor layer, shown in the flow chart of FIG. 18, is now complete (STEP 1890).

FIG. 24 is a cross-sectional view that shows the resultant final structure 2400, including the GaN epilayer 120 bonded to the host substrate 2210, to provide an N-face structure. This epilayer/substrate structure 2400 can now be used by itself or as a structure to create other semiconductor structures. For example, it may be noted that the structure 500 shown in FIG. 6 has a similar configuration, and therefore the epilayer substrate structure 2400 may be utilized in a similar process to make a Ga-face structure such as that shown in FIG. 14.

### (5) Transfer Direct Bonding by Supporting Layer

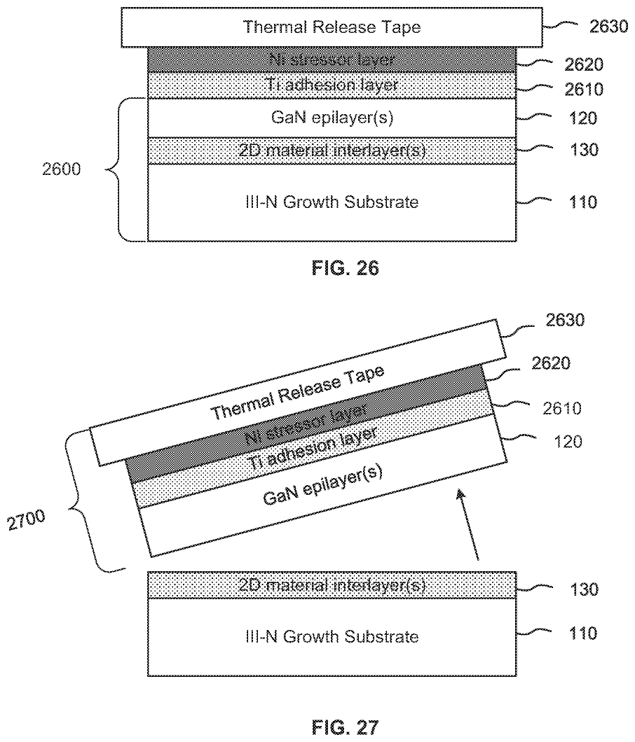

Transfer direct bonding process by supporting layer includes: 1) depositing a double stressor layer to a critical thickness on III-N, III-V, II-VI, SiC, complex oxides, or other oxides epilayers, 2) applying a thermal release tape to the surface of the double stressor layer, 3) mechanically guiding the fracture front across the weak van der Waals interactions dominating the surface of 2D material interlayers, 4) coating a supporting layer on a substrate (e.g., glass or Si), attaching epilayers on the supporting layer, and after removal of supporting layer, directly transfer bonding the epilayers to the host substrate by, for example a wet transfer base. In one example of transfer direct bonding by supporting layer, PMMA (PolyMethyl Methacrylate) is used as the supporting layer (FIG. 26). PMMA is a known synthetic resin (e.g., the material in Plexiglass®).

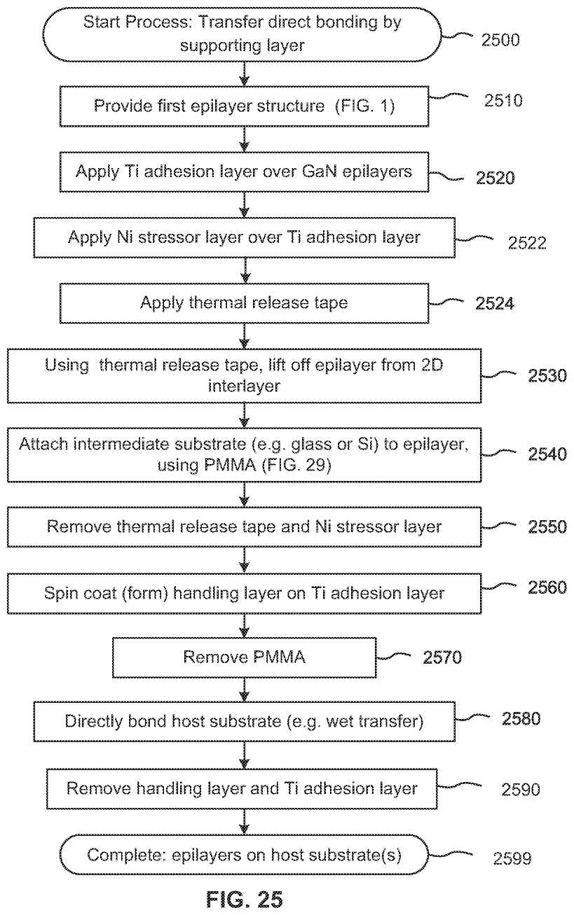

FIG. 25 is a flow chart that shows steps of the transfer method that uses a supporting layer for directly bonding a membrane to a host substrate, to create a semiconductor membrane structure. The following FIGS. 26-33 are cross-sectional views of multilayer structures at intermediate and result stages of the transfer process. Alternative embodiments are also disclosed.

FIG. 26 is a cross-sectional view of a film structure in which thermal release tape 2630 has been applied over a Ti/Ni stressor layer 2620, formed on top of an initial epilayer structure 2600. The wafer bonding process starts (STEP 2500, FIG. 25) by providing (STEP 2510), an initial epilayer structure 2600 (FIG. 26) including a III-N growth substrate 110; a plurality of GaN epilayers 120, and a 2D material interlayer 130 situated between the substrate and the epilayers. The initial epilayer structure 2600 is shown in FIG. 26 and is also described with reference to FIG. 1.

A Ti adhesion layer 2610 is formed over the epilayers (STEP 2520); and a Ni stressor layer 2620 is formed over the Ti adhesion layer STEP 2522). The Ni stressor layer 2620 and the Ti adhesion layer 2610 define a double layer stressor layer, and are grown on top of the GaN epilayers 120 in an orientation with the Ga-face on top and the N-face on the bottom adjacent to the formed 2D interlayers 130, by direct growth on the III-Nitrides growth substrate 110. In one embodiment, a Ni layer 2620 with a thickness ranging from 0.1 um to 1 um is grown by DC magnetron sputtering and a Ti layer 2610 with a thickness ranging from 1 nm to 100 nm may be grown by electron beam evaporation at about room temperature. In other embodiments, a single layer, using appropriate alloys may be used instead the two layers 2610, 2620.

Next the thermal release tape 2630 is applied. Particularly (STEP 2524) a thermal release tape 2630 is attached to the top surface of the Ni stressor layer 2620, which provides the intermediate structure shown in FIG. 26.

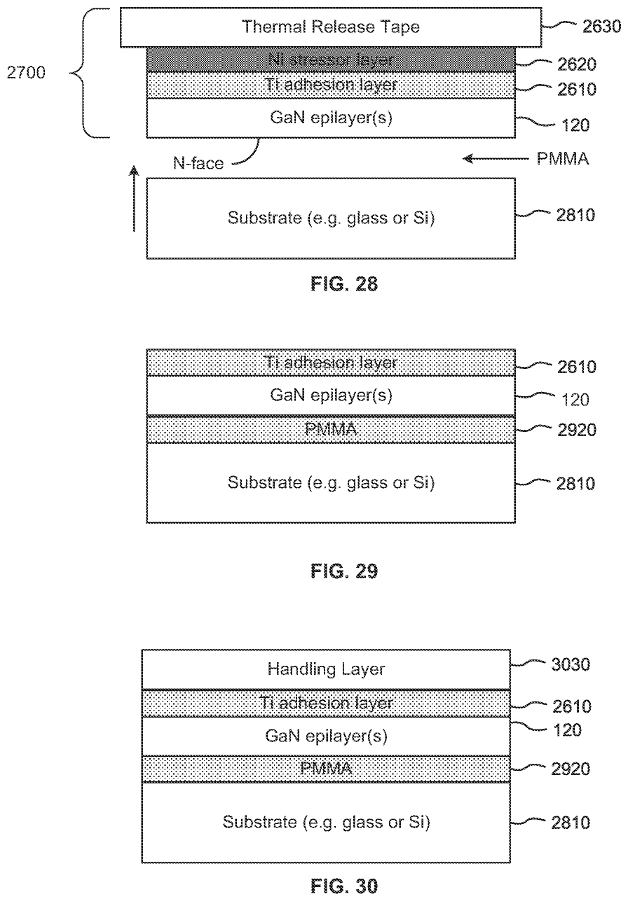

FIG. 27 is a cross-sectional view illustrating exfoliation of the GaN epilayers and 2D material interlayers in the 2DLT process. Particularly as shown in FIG. 27, the Ni stressor layer 2620, the Ti adhesion layer 2610, and the GaN epilayers 2630 are lifted off (STEP 2530) from the substrate 110 and the 2D interlayers 130, using the thermal release tape 1940. This can be performed by mechanically guiding the fracture front across the weak van der Waals interactions dominating the surface of 2D material interlayers. The lifted-off structure is shown at 2700 in FIGS. 27 and 28.

Next, (STEP 2540) an intermediate substrate (such as glass or Si) shown at 2810 in FIG. 28 will be attached to the N-face of the epilayer 120 in the lifted-off structure 2700. FIG. 28 is a cross-sectional view that shows the intermediate substrate 2810 prior to attachment to the N-face of the epilayers 120.

The substrate 2810 is attached to the epilayers 120 using PMMA, which is a synthetic resin. FIG. 29 is a cross-sectional diagram that shows a PMMA supporting layer 2920 that attaches the lifted-off GaN epilayers 120 onto the coated glass or Si substrate 2810. The PMMA layer may be formed using a spin coater. The PMMA supporting layer 2920 is cured after being formed at spin speeds ranging between 1,000 rpm to 6,000 rpm, and spin times ranging between 1 second and 180 seconds. The selected spin speeds and times are closely related to the desired thickness of the PMMA supporting layer.

The thermal release tape 2630 and the Ni stressor layer 2620 are removed (STEP 2550), as shown in the cross-section of FIG. 29, which exposes the Ti adhesion layer 2610. The thermal release tape 2630 may be removed by melting the adhesive material between the Ni stressor layer 2620 and the release tape 2630 at temperatures ranging from 120° C. to 180° C. using a hot plate. The thermal release tape 2630 may be removed before or after bonding the substrate 2810 to the epilayers. The Ni stressor layer 2620 may be removed by a ferric chloride (FeCl₃) etchant.

FIG. 30 is a cross-sectional view of the film structure of FIG. 29 after a handling layer 3030 has been coated on top of Ti adhesion layer 2610.

Next (STEP 2560, FIG. 25) the handling layer 3030 is coated on top of Ti adhesion layer 2610, as shown in the cross-sectional view of FIG. 30. In one embodiment, a polyimide (Pl) or SOG handling layer is coated on top of Ti adhesion layer by a spin coater with spin speeds ranging between about 1,000 rpm to 6,000 rpm and spin times ranging between 1 second and 180 second.

After completing the spin coating process to coat the handling layer 3030, the handling layer is cured, for example at a curing temperature ranging from about 100° C. to 600° C. and a curing time ranging from 1 minute to 180 minutes under a nitrogen atmosphere in a vacuum oven.

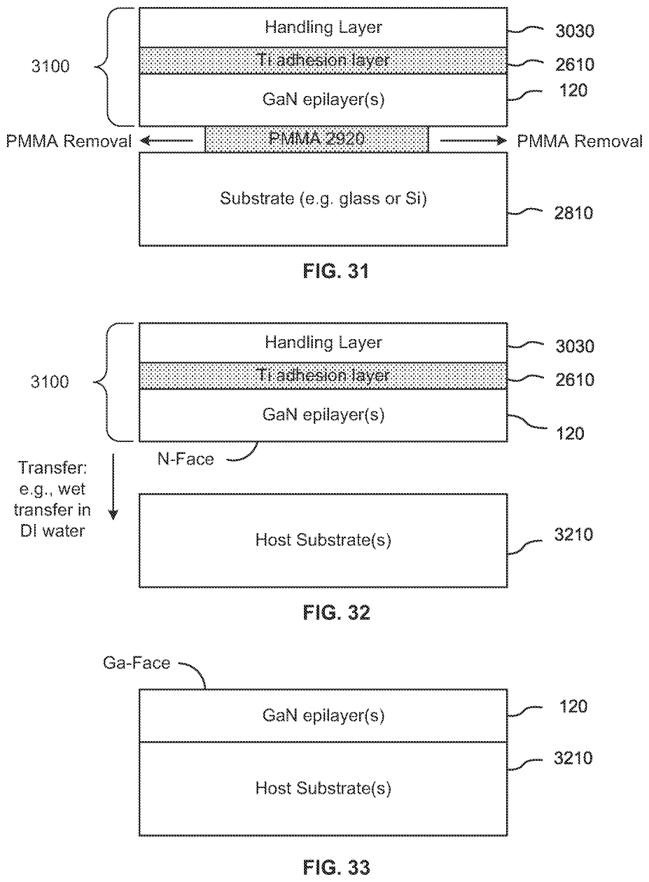

FIG. 31 is a cross-sectional view of the film structure of FIG. 30 illustrating removal of the PMMA supporting layer 2920 from the gap between the epilayer 120 and the substrate 2810. The next step in FIG. 25 (STEP 2570) shows the PMMA layer 2920 removed from the gap between the epilayer 120 and the substrate 2810. The PMMA layer 2920 is removed to provide the intermediate structure 3100 shown in FIG. 31, including the handling layer 3030, the Ti adhesion layer 2610, and the GaN epilayer 120, with its N-face exposed. For example, the PMMA supporting layer 2920 may be removed in a wet process, through immersing film structures (handling layer/Ti adhesion layer/GaN epilayers/PMMA supporting layer/glass or Si substrate) in an acetone solvent that flows into the gap between the epilayer 120 and substrate 2810.

FIG. 32 is a cross-sectional view of the film structure of FIG. 31 after removal of the PMMA supporting layer 2920, illustrating that the GaN epilayers in the intermediate structure 3100 may then be wet transfer direct bonded onto the host substrate 3210 in DI water. Referring back to FIG. 25, the next step (STEP 2580) shows that the intermediate structure 3100 is directly bonded onto a host substrate 3210 so that the exposed N-face of the epilayer 120 is attached to the host substrate 3210. For example, the intermediate structure 3100 (the GaN epilayers with handling layer and Ti adhesion layer released from glass or Si substrate) can be wet-transfer direct bonded onto the host substrates 3210 in DI water (FIG. 32). Preferably, the host substrate 3210 has a thermal expansion coefficient that nearly matches that of GaN, so that the host substrate 3210 closely thermally matches the GaN epilayers 120.

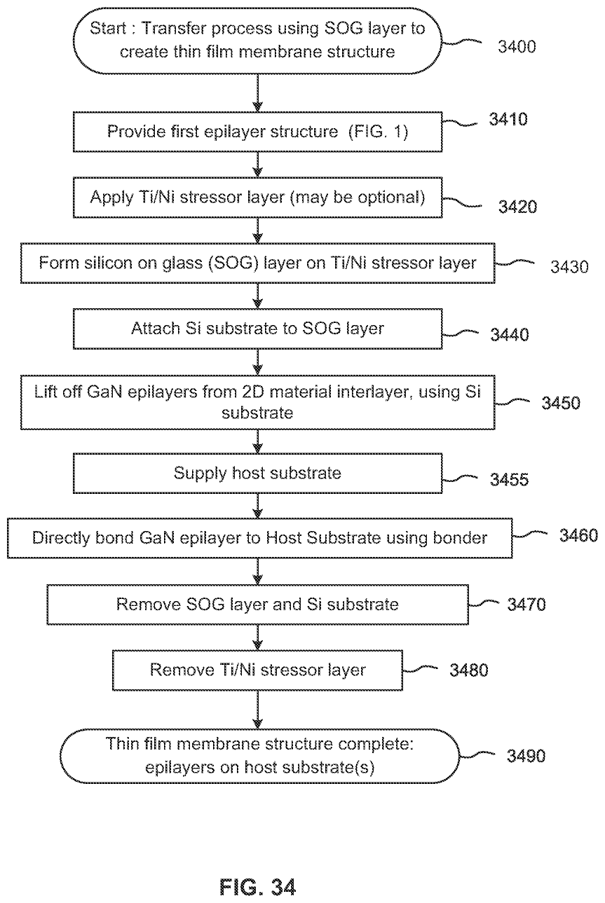

After attaching the epilayers 120 to the host substrate 3210, the handling layer 3030 and the Ti adhesion layer are removed (STEP 2590), to provide a final structure (FIG. 33) that includes the GaN epilayers 120 attached to the host substrate 3210, with the Ga-face of the epilayers exposed.

The handling layers 3030 may be removed, for example via oxygen plasma reactive ion etching (RIE). In one embodiment, power in a range between 10 W and 1,000 W is applied to the RF coil to generate the oxygen plasma. The gas pressure in the chamber is kept at pressure ranged with 10 mTorr to 1,000 mTorr. Total exposure time to oxygen plasma dry etching is optimized in the range of 1 minute to 10 minutes. The oxygen flow rate may be optimized in a range of 1 seem to 100 sccm.

The Ti adhesion layer 2610 may be removed by an appropriate etchant such as buffered oxide etchant (BOE) or chromium etchant.

The direct bonding by supporting layer shown in the flow chart of FIG. 25 is now complete (STEP 2599). FIG. 33 is a cross-sectional view that shows the resultant final structure, including the GaN epilayer 120 bonded to the host substrate 3210, which provides a Ga-faced structure. This structure can now be used by itself or as a structure to create other semiconductor structures.

### (6) Transfer Direct Bonding by SOG Layer

Transfer direct bonding process using a SOG (Spin On Glass) layer includes depositing a stressor layer to a critical thickness on III-N, III-V, II-VI, SiC, complex oxides, or other oxides epilayers, coating a SOG layer on the surface of the stressor layer, applying a Si substrate to the surface of the SOG layer, mechanically guiding the fracture front across the weak van der Waals interactions dominating the surface of 2D material interlayers, and directly transfer bonding between the epilayers and the host substrate by, e.g., a conventional wafer bonder.

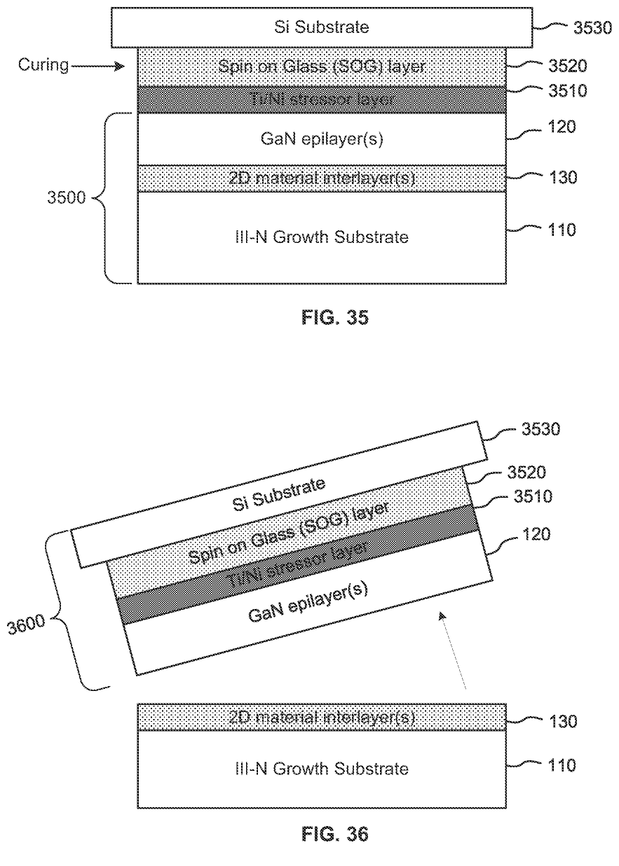

FIG. 34 is a flow chart that shows steps of the transfer method that includes directly bonding a membrane to a host substrate and uses a SOG (Spin on glass) layer, to create a thin film GaN membrane structure. The following FIGS. 35-39 are cross-sectional views of multilayer structures at intermediate and result stages of the transfer process. Alternative embodiments are disclosed.

The transfer process (STEP 3400) starts by providing (STEP 3410), an initial epilayer structure 3500 (FIG. 35) including a III-N growth substrate 110; a plurality of GaN epilayers 120, and a 2D material interlayer 130 situated between the substrate and the epilayers. The initial epilayer structure is shown in FIG. 35 at 3500 and is also described with reference to FIG. 1.

Next (STEP 3420) a Ti/Ni stressor layer 3510 is formed on the top surface of the epilayer 120. Particularly, the Ti/Ni stressor layers 3510 have the form of double layer of Ti/Ni, grown on top of the GaN epilayers 120, with the Ga-face on top and the N-face on the bottom adjacent to the 2D interlayers 130 formed by direct growth on III-Nitrides substrate 110. The cross-section of FIG. 35 shows the Ti/Ni stressor layer 3510 formed on the top surface of the epilayer 120. In some embodiments, depending upon the materials, the Ti/Ni stressor layer 3510 may be omitted, and would be optional in those embodiments.

Next (STEP 3430) a SOG layer 3520 is formed on the Ti/Ni stressor layer 3510. While curing the SOG layer 3520, a substrate (e.g., Si) 3530 is attached to the SOG layer (STEP 3440), so that when the SOG layer is cured, the Si substrate is attached to the SOG layer. The SOG layer 3520 is formed (coated) on top of Ti/Ni stressor layer by a spin coater (not shown) in a similar manner as the handling layer 3030 shown in FIG. 30, and then the Si substrate 3530 is applied on the SOG layer 3520. The SOG layer may be cured, for example at a curing temperature ranging from about 100° C. to 600° C. and a curing time ranging from 1 minute to 180 minutes under a nitrogen atmosphere in a vacuum oven (not shown). In alternative embodiments, the SOG layer 3520 may utilize a different material (other than glass) that has similar properties and can be removed by etching under the Si substrate 3530.

FIG. 36 is a cross-sectional view of the film structure including the SOG layer 3520, stressor layers 3510, and GaN epilayers 120 being lifted off from the substrate 110 at the 2D material interface. Referring to the flow chart of FIG. 34 (STEP 3450) after the SOG layer 3520 has cured, the epilayers are lifted off (exfoliated) from the 2D interlayers 130 in the process as shown in the cross section of FIG. 36, thereby providing an intermediate structure 3600 including the Si substrate 3530, the SOG layer 3520, the Ti/Ni stressor layer 3510, and the epilayers 120.

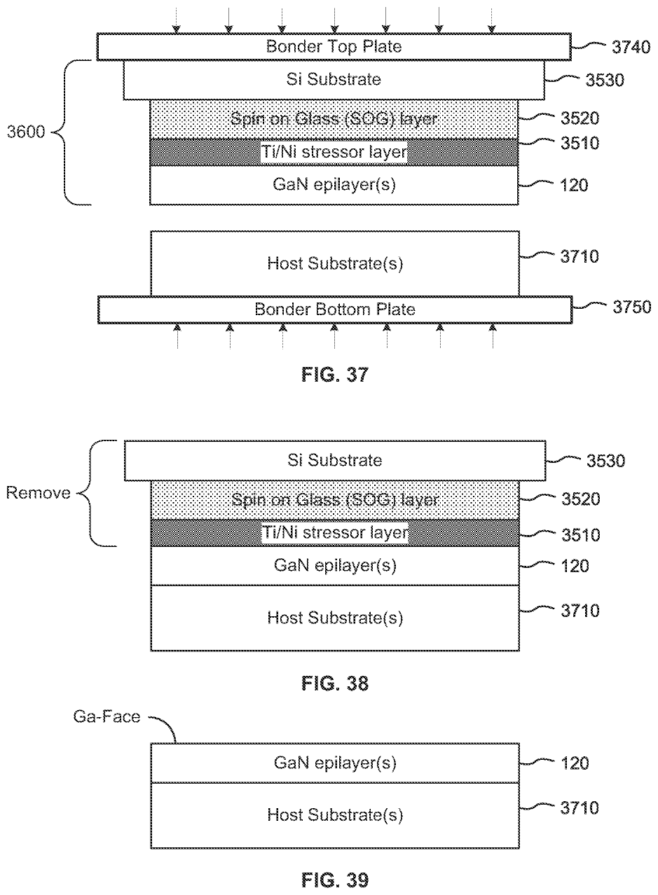

Next, as illustrated in the cross-section of FIG. 37, a host substrate 3710 is supplied (STEP 3455), and the host substrate 3710 is directly bonded to the bottom surface of the GaN epilayers 120 (STEP 3460) using a conventional wafer bonder that has a top plate 3740 and a bottom plate 3750. Particularly, FIG. 37 is a cross-sectional view showing the lifted-off GaN epilayers 120 (with the SOG layer, Ti/Ni stressor layer, and Si substrate) being transferred onto the host substrate 3710. The GaN epilayer 120 and the host substrate 3710 are directly bonded at bonding conditions (such as temperature, pressure, and time) under a chamber vacuum of for example 10⁻³ Torr.

FIG. 38 is a cross sectional view of the structure resulting from bonding the epilayer 120 with the host substrate 3710 in FIG. 37. After bonding between GaN epilayers and host substrates, the SOG layer 3520 and the Si substrate 3550 are removed (STEP 3470, FIG. 34). The Si substrate 3550 may be detached by removal of the SOG layer 3520, which may be removed for example using the oxygen plasma reactive ion etching (RIE) process for the handling layer 3030 (see FIG. 32). For example, power in a range between 10 W and 1,000 W is applied to the RF coil to generate the oxygen plasma. The gas pressure in the chamber is kept at pressure ranged with 10 mTorr to 1,000 mTorr. Total exposure time to oxygen plasma dry etching is optimized in the range of 1 minute to 10 minutes. The oxygen flow rate may be optimized in a range of 1 seem to 100 sccm.

Next the Ti/Ni/stressor layer 3510 is removed (STEP 3480). The Ni may be removed by a ferric chloride (FeCl₃) etchant and the Ti adhesion layer may be removed by an appropriate etchant such as buffered oxide etchant (BOE) or chromium etchant.

The transfer process using a SOG layer, shown in the flow chart of FIG. 34 is now complete (STEP 3490). FIG. 39 is a cross-sectional view that shows the resultant final structure, including the GaN epilayer 120 directly bonded to the host substrate 3710, which exposes the Ga-face and provides a Ga-faced structure. Therefore, we obtain bonded GaN epilayers and host substrates. This structure can now be used by itself or as a structure to create other semiconductor structures.

### CONCLUSION

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A method of fabricating a compound semiconductor thin film structure, comprising:
epitaxially forming compound semiconductor epilayers over a 2D material interlayer on a growth substrate;
lifting off the epilayers from the 2D material interlayer;
directly bonding a host substrate to the bottom surface of the compound semiconductor epilayers; and
exposing the top surface of the compound semiconductor epilayers to provide a thin film structure.

2. A method of fabricating a Ga-face thin film structure including a III-nitride (GaN) membrane, comprising:
epitaxially forming III-nitride GaN epilayers over a 2D material interlayer on a growth substrate;
lifting off the GaN epilayers from the 2D material interlayer;
directly bonding a host substrate to the bottom surface of the GaN epilayers; and
exposing the top surface of the GaN epilayers to provide a Ga-face thin film structure.

3. The fabrication method of claim 2 further comprising:
prior to lifting off the epilayers, directly wafer bonding a top host substrate to the top surface of the GaN epilayer; and
exposing the top surface of the GaN epilayers includes removing the top host substrate.

4. The fabrication method of claim 2 further comprising:
prior to lifting off the epilayers, depositing a stressor layer over the GaN epilayers and applying a thermal release tape over the stressor layer; and
exposing the top surface of the GaN epilayers includes removing the thermal release tape and the stressor layer.

5. The fabrication method of claim 4 wherein depositing a stressor layer includes:
depositing a Ti adhesion layer over the epilayers; and
depositing an Ni stressor layer over the Ti adhesion layer.

6. The fabrication method of claim 2 further comprising:
prior to lifting off the epilayers, forming a Ti/Ni stressor layer on the top surface of the GaN epilayer, forming a spin on glass (SOG) layer on the Ti/Ni stressor layer, and attaching a substrate to the SOG layer while curing the SOG layer, so that the substrate is attached when cured; and
exposing the top surface of the GaN epilayers includes removing the SOG layer, the substrate, and the Ti/Ni stressor layer.

7. A method of fabricating a GaN membrane thin film structure using direct wafer bonding, comprising:
epitaxially forming GaN epilayers over a 2D material interlayer on a growth substrate;
directly wafer bonding a first host substrate to the top surface of the GaN epilayer;
lifting off the GaN epilayers and the first host substrate from the 2D material interlayer to expose the bottom surface of the GaN epilayers;
directly bonding a second host substrate to the bottom of the epilayers; and
removing the first host substrate from GaN epilayers to expose the top surface of the GaN epilayers and thereby provide a Ga-face thin film structure including the GaN epilayers and the second host substrate.

8. The fabrication method of claim 7 wherein directly wafer bonding the first host substrate to the GaN epilayer is performed in a wafer bonder.

9. The fabrication method of claim 7 wherein lifting off the GaN epilayers includes applying mechanical shear force.

10. The fabrication method of claim 7 wherein lifting off includes mechanically guiding the fracture front across the weak van der Waals interactions dominating the surface of 2D material interlayers.

11. The fabrication method of claim 7 wherein removing the first host substrate from the GaN epilayer includes wafer grinding the first host substrate and polishing the GaN epilayer.

12. A method of fabricating a GaN membrane thin film structure using two stressor layers, comprising:
epitaxially forming GaN epilayers over a 2D material interlayer on a growth substrate;
depositing a first stressor layer over the GaN epilayers;
applying a first thermal release tape over the first stressor layer;
using the thermal release tape to lift off the GaN epilayers from the 2D material interlayer on the growth substrate, thereby exposing the bottom surface of the GaN epilayers;
depositing a second stressor layer on the bottom surface of the GaN epilayers;
applying a second thermal release tape over the second stressor layer;
removing the first thermal release tape;
removing the first stressor layer;
directly bonding the top surface of the GaN epilayers to a host substrate;
removing the second release tape; and
removing the second stressor layer from the epilayers to expose the top surface of the GaN epilayers and thereby provide an N-face thin film structure including the GaN epilayers and the host substrate.

13. The fabrication method of claim 12 wherein directly bonding the bottom surface of the GaN epilayers to the host substrate is performed in a wafer bonder, and the second release tape is removed prior to the direct bonding in the wafer bonder.

14. The fabrication method of claim 12 wherein depositing the first stressor layer includes:
depositing a Ti adhesion layer over the epilayers; and
depositing an Ni stressor layer over the Ti adhesion layer.

15. The fabrication method of claim 12 wherein
removing the first and second release tapes includes applying thermal energy; and
removing the first and second stressor layers includes applying chemical etchants.

16. A method of fabricating a GaN membrane thin film structure using a supporting layer, comprising:
epitaxially forming GaN epilayers over a 2D material interlayer on a growth substrate;
depositing a Ti adhesion layer over the epilayers;
depositing an Ni stressor layer over the Ti adhesion layer;
applying thermal release tape to the Ni stressor layer;
using the thermal release tape, lifting off the GaN epilayers from the 2D materials layer and the growth substrate to expose the bottom surface of the GaN epilayers;
applying a PMMA layer to the bottom surface and attaching an intermediate substrate to PMMA layer to attach the intermediate substrate;
removing the release tape, and removing the Ni stressor layer, to expose the Ti adhesion layer;
forming a handling layer on the Ti adhesion layer;
removing the PMMA layer between the epilayer and the intermediate substrate to expose the N-face of the GaN epilayers and provide an intermediate structure including the handling layer, the Ti adhesion layer, and the GaN epilayers;
directly bonding the intermediate structure onto a host substrate so that the exposed N-face is attached to the host substrate; and
removing the handling layer and the Ti adhesion layer, to provide a final structure that includes the GaN epilayers attached to the host substrate, with the Ga-face of the GaN epilayers exposed.

17. The fabrication method of claim 16 wherein the intermediate substrate comprises one of Si and glass.

18. The fabrication method of claim 16 wherein directly bonding the intermediate structure onto a host substrate includes a wet transfer process.

19. The fabrication method of claim 16 where in the release tape is removed in a thermal process, and the Ni stressor layer is removed in a chemical process.

20. A method of fabricating a GaN membrane thin film structure using a silicon on glass (SOG) layer, comprising:
epitaxially forming GaN epilayers over a 2D material interlayer on a growth substrate;
forming a Ti/Ni stressor layer on the top surface of the GaN epilayer;
forming an SOG layer on the Ti/Ni stressor layer;
attaching a substrate to the SOG layer;
lifting off the epilayers from the 2D materials, thereby providing an intermediate structure including the Si substrate, the SOG layer, the Ti/Ni stressor layer, and the epilayers;
directly bonding a host substrate to the exposed surface of the GaN epilayers;
removing the SOG layer and the Si substrate;
removing the Ti/Ni/stressor layer to expose the top surface of the GaN epilayers and thereby provide a Ga-face thin film structure including the GaN epilayers and the host substrate.

21. The fabrication method of claim 20 wherein the substrate comprises Si, and the Si substrate is attached to the SOG layer while the SOG layer is curing, so that the Si substrate is attached when the SOG layer is cured.

22. The fabrication method of claim 20 wherein directly bonding the host substrate to the expose surface of the GaN epilayers the host substrate is performed in a wafer bonder.

23. The fabrication method of claim 20 wherein depositing the Ti/Ni stressor layer includes:
depositing a Ti adhesion layer over the epilayers; and
depositing an Ni stressor layer over the Ti adhesion layer.

24. A method of fabricating an N-face GaN membrane thin film structure using direct wafer bonding, comprising:
epitaxially forming GaN epilayers over a buffer layer and a 2D material interlayer on a growth substrate, providing an exposed top surface of the GaN epilayers;
directly wafer bonding a host substrate to the top surface of the GaN epilayers;
lifting off the GaN epilayers and the first host substrate from the 2D material interlayer to expose the buffer layer attached to the bottom surface of the GaN epilayers;
removing the buffer layer from the GaN epilayers to expose the bottom surface of the GaN epilayers and thereby provide an N-face thin film structure including the GaN epilayers and the host substrate.

25. The fabrication method of claim 24 wherein directly wafer bonding the first host substrate to the GaN epilayer is performed in a wafer bonder.

26. The fabrication method of claim 24 wherein lifting off the GaN epilayers includes applying mechanical shear force.

27. A method of fabricating a GaN membrane, comprising:
epitaxially forming GaN epilayers over a 2D material interlayer on a growth substrate;
directly wafer bonding a host substrate to the top surface of the GaN epilayer;
lifting off the GaN epilayers and the host substrate from the 2D material interlayer;
removing the host substrate from the GaN epilayers to provide a GaN membrane.

28. The fabrication method of claim 27 wherein directly wafer bonding the first host substrate to the GaN epilayer is performed in a wafer bonder.

29. The fabrication method of claim 27 wherein lifting off the GaN epilayers includes applying mechanical shear force.

30. The fabrication method of claim 27 wherein removing the first host substrate from the GaN epilayer includes wafer grinding and polishing the GaN epilayer.
